(19) United States
(12) Patent Application Publication
(10) Pub. No.: US 2025/0210563 A1
(43) Pub. Date: Jun. 26, 2025

(54) SEMICONDUCTOR DEVICE

(71) Applicant: SHINKO ELECTRIC INDUSTRIES CO., LTD., Nagano-shi (JP)

(72) Inventor: Shinichiro SEKIJIMA, Nagano-shi (JP)

(21) Appl. No.: 18/999,101

(22) Filed: Dec. 23, 2024

(30) Foreign Application Priority Data
Dec. 26, 2023 (JP) 2023-219001

(51) Int. Cl. H01L 23/00; H01L 23/31; H01L 23/498

(52) U.S. Cl. CPC H01L 24/16; H01L 23/3157; H01L 23/49822; H01L 24/06; H01L 24/14; H01L 24/32; H01L 24/73; H01L 2224/06131; H01L 2224/14; H01L 2224/16227; H01L 2224/16238; H01L 2224/32225; H01L 2224/73204; H01L 2924/1815

(57) ABSTRACT

A semiconductor device includes a wiring substrate, a semiconductor element, a bonding member bonding connection pads of the wiring substrate and electrode pads of the semiconductor element, and an encapsulation resin provided between the wiring substrate and the semiconductor element. The connection pads each include a first body, first projections projecting from the first body toward a central region of the semiconductor element, and a first recess. The bonding members each include a second body, second projections projecting from the second body toward the central region, and a second recess. A first space surrounded by the upper surface of the substrate body, the wall surface of the first recess, the wall surface of the second recess, and the lower surface of each of the electrode pads is open in a single direction.

### CROSS-REFERENCE TO RELATED APPLICATIONS

This application is based upon and claims the benefit of priority from Japanese Patent Application No. 2023-219001, filed on Dec. 26, 2023, the entire contents of which are incorporated herein by reference.

### BACKGROUND

### 1. Field

This disclosure relates to a semiconductor device.

### 2. Description of Related Art

Japanese Laid-Open Patent Publication No. 2010-278070 discloses an example of a semiconductor device that includes a wiring substrate, a semiconductor element mounted on the wiring substrate, and an encapsulation resin arranged between the wiring substrate and the semiconductor element.

### SUMMARY

In the semiconductor device described above, improvement in the reliability of electrical connection between the wiring substrate and the semiconductor element is desired.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor device includes a wiring substrate including a substrate body and connection pads formed on an upper surface of the substrate body, a semiconductor element mounted on the wiring substrate and including electrode pads, a bonding member bonding the connection pads to the electrode pads, and an encapsulation resin arranged between the wiring substrate and the semiconductor element. The connection pads each include a first body, first projections projecting from the first body toward a central region of the semiconductor element in plan view, and a first recess surrounded by the first body and the first projections in plan view. The bonding member includes a second body formed on the first body, second projections formed on the first projections and projecting from the second body toward the central region of the semiconductor element in plan view, and a second recess surrounded by the second body and the second projections in plan view. A first space surrounded by the upper surface of the substrate body, a wall surface of the first recess, a wall surface of the second recess, and a lower surface of the electrode pads is open in a single direction.

Other features and aspects will be apparent from the following detailed description, the drawings, and the claims.

### BRIEF DESCRIPTION OF THE DRAWINGS

FIG. 1 is a schematic plan view illustrating an embodiment of a semiconductor device.

FIG. 2 is a schematic cross-sectional view illustrating the semiconductor device taken along line 2-2 in FIG. 1.

FIG. 3 is a schematic cross-sectional view illustrating the semiconductor device taken along line 3-3 in FIG. 1.

FIG. 4 is a schematic plan view illustrating a wiring substrate arranged in the semiconductor device illustrated in FIG. 1.

FIG. 5 is a schematic perspective view illustrating a portion of the semiconductor device illustrated in FIG. 1.

FIG. 6 is a schematic cross-sectional view illustrating an exemplary manufacturing process in a method for manufacturing the semiconductor device of the embodiment.

FIG. 7 is a schematic cross-sectional view illustrating a subsequent exemplary manufacturing process.

FIG. 8 is a schematic plan view illustrating a structural body illustrated in FIG. 7.

FIG. 9 is a schematic cross-sectional view illustrating a subsequent exemplary manufacturing process.

FIGS. 10, 11, and 12 are each a schematic plan view illustrating an example of a flowing action of an encapsulation resin in the manufacturing process illustrated in FIG. 9.

FIGS. 13, 14, 15, and 16 are each a schematic plan view of a semiconductor device in various modified examples.

FIG. 17 is a schematic cross-sectional view illustrating a further modified example of a semiconductor device.

FIG. 18 is a schematic plan view illustrating a semiconductor device according to a comparative example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

An embodiment will now be described with reference to the accompanying drawings.

In the accompanying drawings, elements are illustrated for simplicity and clarity and have not necessarily been drawn to scale. To facilitate understanding, hatching lines may not be illustrated or may be replaced by shadings in the cross-sectional drawings. In the planar drawings, to facilitate understanding of the planar shape of each member, hatching may be provided to the member. In each drawing, the X-axis, the Y-axis, and Z-axis extend orthogonal to each other. In the description hereafter, for the sake of convenience, a direction extending along the X-axis is referred to as the X-axis direction, a direction extending along the Y-axis is referred to as the Y-axis direction, and a direction extending along the Z-axis is referred to as the Z-axis direction. In the present specification, the term “plan view” refers to a view of an object in the Z-axis direction, unless otherwise specified. In the present specification, the term “planar shape” refers to a shape of an object as viewed in the Z-axis direction, unless otherwise specified. In the present specification, the terms “up”, “down”, “left”, and “right” correspond to directions when the drawings are oriented to an appropriate position allowing reference numerals of the elements to be read correctly. In this specification, the terms “faced” and “facing” refer to a state in which surfaces or members are located in front of each other. The terms are not limited to a state in which the surfaces or members are located completely in front of each other and include a state in which the surfaces or members are located partially in front of each other. In this specification, the terms “faced” and “facing” further include both a state in which two parts are located with another member located between the two parts and a state in which another member is not located between the two parts. In this specification, “equal” includes exactly equal and a case in which compared subjects differ from each other slightly due to dimensional tolerances or the like. In addition, in the description of the present disclosure, the numerical range of “X1 to X2” defined by an upper limit value X1 and a lower limit value X2 refers to being greater than or equal to X1 and less than or equal to X2, unless otherwise specified.

### General Structure of Semiconductor Device 10

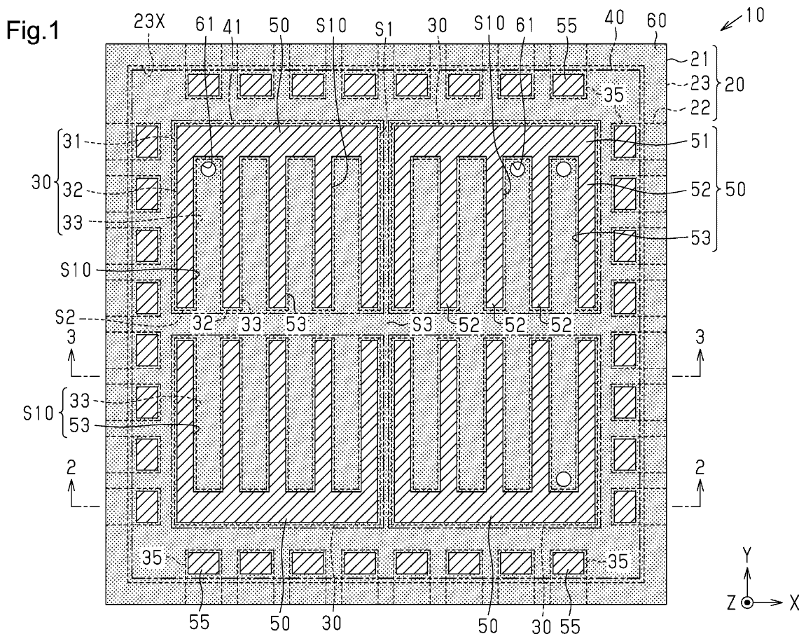

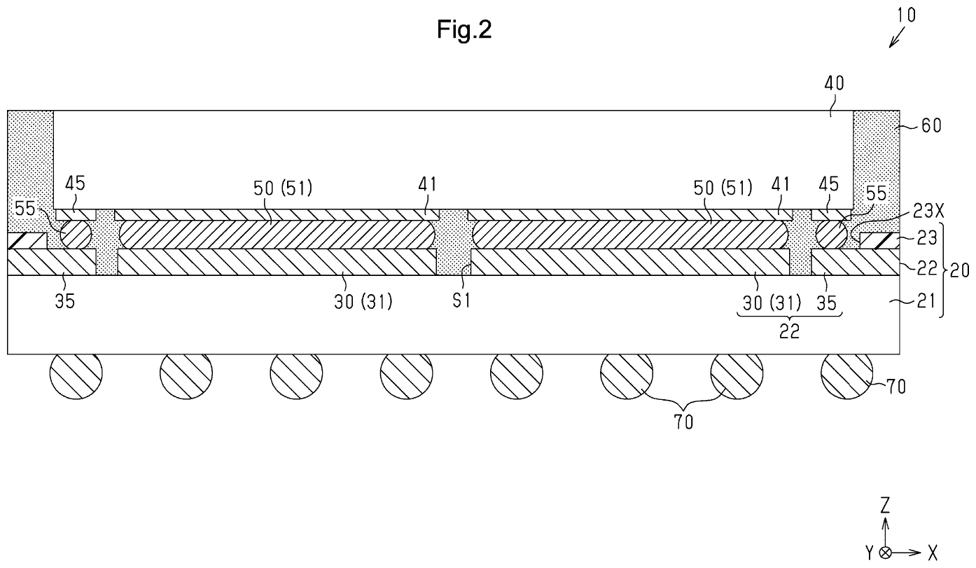

As illustrated in FIGS. 1 and 2, a semiconductor device 10 includes a wiring substrate 20, one or more (one in the present embodiment) semiconductor elements 40 mounted on an upper surface of the wiring substrate 20, and bonding members 50 and 55 bonding the wiring substrate 20 to the semiconductor element 40. As illustrated in FIG. 2, the semiconductor device 10 includes an encapsulation resin 60, which is arranged between the wiring substrate 20 and the semiconductor element 40, and external connection terminals 70. FIG. 1 is a plan view of the semiconductor device 10 illustrated in FIG. 2 taken from above.

In FIG. 1, the semiconductor element 40 is transparently illustrated.

### Structure of Wiring Substrate 20

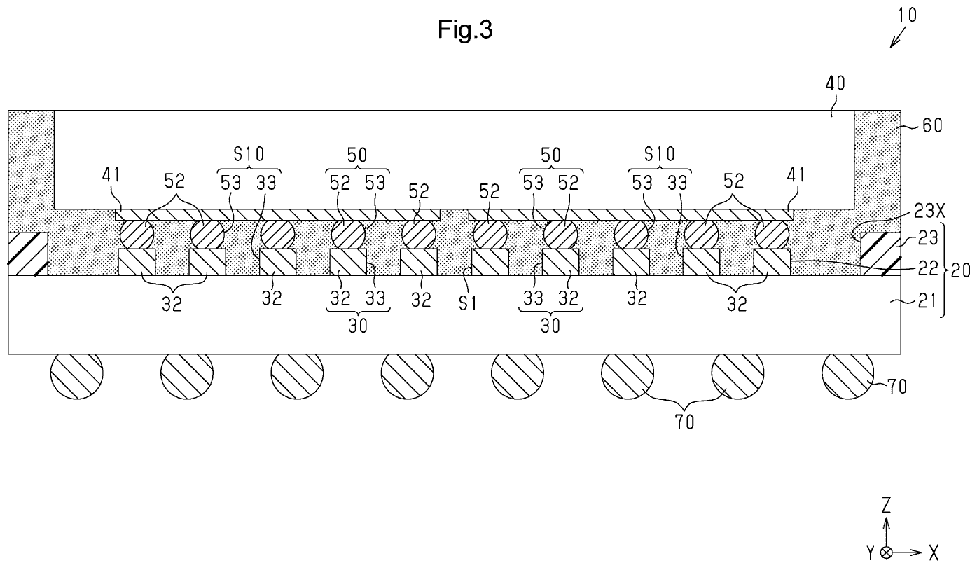

As illustrated in FIGS. 2 and 3, the wiring substrate 20 includes, for example, a substrate body 21, a wiring layer 22, and a solder resist layer 23.

The substrate body 21 may be a wiring structural body in which insulating resin layers and wiring layers are alternately stacked. In an example, the wiring structural body may, but does not necessarily have to, include a core substrate. The material of the insulating resin layer may be, for example, a thermosetting insulating resin. The thermosetting insulating resin may be, for example, an insulating resin such as an epoxy resin, a polyimide resin, or a cyanate resin. Further, the material of the insulating resin layer may be, for example, an insulating resin in which the main component is a photosensitive resin such as a phenol-based resin or a polyimide-based resin. The insulating resin layer may include, for example, a filler such as silica or alumina. The thickness of the substrate body 21 may be, for example, approximately 50 μm to 200 μm.

As illustrated in FIG. 1, the substrate body 21 is, for example, rectangular in plan view. However, the planar shape of the substrate body 21 is not limited to a rectangle and may be any shape. The substrate body 21 is greater in planar size than the semiconductor element 40. The planar size of the substrate body 21 may be, for example, approximately from 5 mm×5 mm to 20 mm×20 mm.

As illustrated in FIGS. 2 and 3, the wiring layer 22 is formed on an upper surface of the substrate body 21. The wiring layer 22 is, for example, electrically connected to the external connection terminals 70 by wiring layers and through electrodes in the substrate body 21. The material of the wiring layer 22 may be, for example, copper (Cu) or a copper alloy.

As illustrated in FIG. 2, the wiring layer 22 includes one or more (in the present embodiment, four) connection pads 30 and one or more (in the present embodiment, thirty-two) connection pads 35. The connection pads 30 and 35 are each an electronic component mount pad electrically connected to the semiconductor element 40.

The solder resist layer 23 is the outermost insulation layer (in the present embodiment, uppermost insulation layer) of the wiring substrate 20. The solder resist layer 23 is formed on the upper surface of the substrate body 21 (refer to FIG. 3). The solder resist layer 23 covers, for example, a portion of the wiring layer 22 (refer to FIG. 2). In an example, the solder resist layer 23 covers the wiring layer 22 arranged in a peripheral region of the upper surface of the substrate body 21. The solder resist layer 23 exposes, for example, the connection pads 30 and 35. The solder resist layer 23 includes an opening 23X extending through the solder resist layer 23 in the thickness-wise direction and exposing the connection pads 30 and 35 and a portion of the upper surface of the substrate body 21.

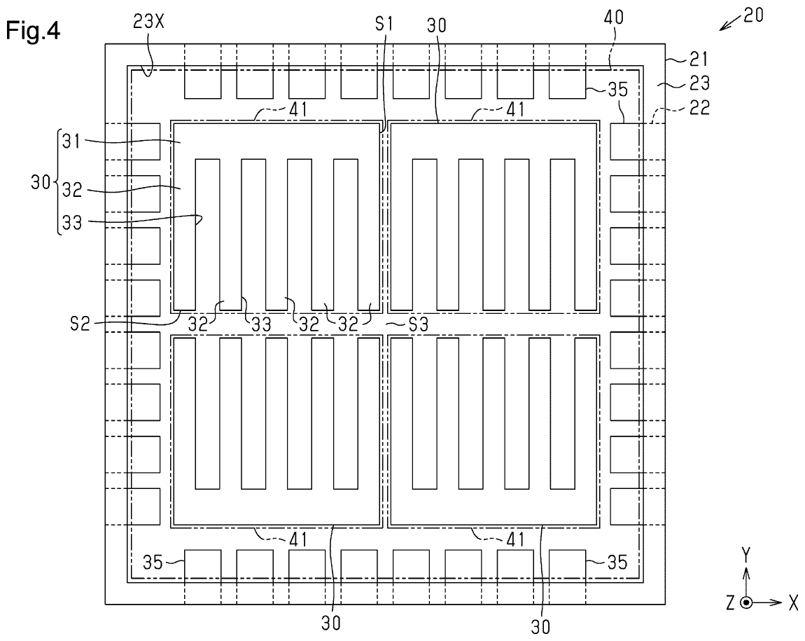

As illustrated in FIG. 4, the opening 23X, for example, overlaps a mount region in which the semiconductor element 40 is mounted in plan view. The opening 23X, for example, overlaps the entirety of the mount region in plan view. The opening 23X is, for example, slightly greater in planar size than the semiconductor element 40. In other words, in plan view, the solder resist layer 23 surrounds the semiconductor element 40. In the present embodiment, the solder resist layer 23 covers the peripheral region of the upper surface of the substrate body 21 along the entire perimeter. The opening 23X exposes, for example, the wiring layer 22 as the connection pads 30 and 35 in the mount region. The opening 23X exposes the upper surface of the substrate body 21 in the mount region.

The material of the solder resist layer 23 may be, for example, an insulating resin including a photosensitive resin, such as a phenol resin or a polyimide resin, as a main component. The solder resist layer 23 may contain, for example, a filler such as silica or alumina.

A surface-processed layer is formed on the surface of the wiring layer 22 exposed from the solder resist layer 23, that is, the surfaces (both upper surface and side surface or only upper surface) of the connection pads 30 and 35, when appropriate. Examples of the surface-processed layer include a gold (Au) layer, a nickel (Ni) layer/Au layer (metal layer in which the Ni layer is used as bottom layer, and the Au layer is formed on the Ni layer), and an Ni layer/palladium (Pd) layer/Au layer (metal layer in which the Ni layer is used as bottom layer, and the Ni layer, the Pd layer, and the Au layer are sequentially stacked). Further examples of the surface-processed layer include an Ni layer/Pd layer (metal layer in which Ni layer serves as bottom layer, and Pd layer is formed on Ni layer), a Pd layer/Au layer (metal layer in which Pd layer serves as bottom layer, and Au layer is formed on Pd layer), or the like. The Au layer is a metal layer formed from Au or an Au alloy. The Ni layer is a metal layer formed from Ni or a Ni alloy. The Pd layer is a metal layer formed from Pd or a Pd alloy. The Au layer, Ni layer, and Pd layer may each be, for example, a metal layer (electroless plating layer) formed by an electroless plating process or a metal layer (electrolytic plating layer) formed by an electrolytic plating process. Alternatively, the surface-processed layer may be an organic solderability preservative (OPS) film formed by performing an anti-oxidation process, such as an OSP process, on the surface of the wiring layer 22. The OSP film may be, for example, a coating of an organic compound such as an azole compound or an imidazole compound.

### Structure of Connection Pad 30

In an example, in plan view, the connection pads 30 are arranged in a central region of the upper surface of the substrate body 21. The connection pads 30 are arranged in a central part of the mount region, in which the semiconductor element 40 is mounted. The connection pads 30 are, for example, arranged in proximity to each other. The connection pads 30 are, for example, arranged in the central part of the mount region in a matrix pattern in plan view (in the present embodiment, 2×2). In the example illustrated in FIG. 4, two of the connection pads 30 are spaced apart from each other and arranged in the X-axis direction. Two of the connection pads 30 are spaced apart from each other and arranged in the Y-axis direction. Each connection pad 30 is spaced apart and faced to a connection pad 30 located next in the X-axis direction and is also spaced apart and faced to a connection pad 30 located next in the Y-axis direction. The two connection pads 30 that are located next to each other in the X-axis direction are spaced apart from each other by a gap S1. The two connection pads 30 that are located next to each other in the Y-axis direction are spaced apart from each other by a gap S2. In an example, the width of the gap S1, that is, the dimension of the gap S1 in the X-axis direction, is less than the width of the gap S2, that is, the dimension of the gap S2 in the Y-axis direction. In the following description, a portion where the gap S1 and the gap S2 overlap each other is referred to as a gap S3. The gap S3 is, for example, located in a planar center of the mount region. In an example, in plan view, the gap S3 is located in the center of the region where the four connection pads 30 are arranged in plan view. The four connection pads 30 are electrically insulated from each other.

Each of the connection pads 30 includes a first body 31, multiple (in the present embodiment, five) first projections 32 projecting from the first body 31 in plan view, and one or more (in the present embodiment, four) first recesses 33 surrounded by the first body 31 and two of the first projections 32 in plan view. In an example, each of the connection pads 30 is entirely comb-tooth-shaped in plan view.

The first body 31 joins the first projections 32 to each other. The first body 31 is, for example, belt-shaped and extends in the X-axis direction. In other words, the first body 31 has a longitudinal direction that conforms to the X-axis direction. The first body 31 has, for example, a given width in the Y-axis direction. In other words, the first body 31 has a width-wise direction conforming to the Y-axis direction. The first body 31 includes outer side surfaces, which are, for example, flush with outer side surfaces of the first projections 32 located at opposite sides (in FIG. 1, outermost sides in the X-axis direction).

Each first projection 32 projects from the first body 31 toward a central region of the semiconductor element 40 in plan view. In an example, the first projection 32 projects from the first body 31 toward one of the connection pads 30 faced to the first projection 32 in the Y-axis direction. The first projection 32 extends in a direction intersecting the longitudinal direction of the first body 31 (in the present embodiment, X-axis direction). In the present embodiment, the first projection extends in the Y-axis direction, which is orthogonal to the longitudinal direction of the first body 31. The first projection 32 is belt-shaped and extends in the Y-axis direction. The first projection 32 has a given width in the X-axis direction. The first projection 32 is formed continuously and integrally with the first body 31. The first projections 32 are arranged at intervals in the longitudinal direction (in the present embodiment, X-axis direction) of the first body 31. In an example, the first projections 32 project parallel to each other. In an example, the first projections 32 project from the first body 31 by the same length. In other words, the longitudinal dimensions of the first projections 32 in the Y-axis direction are equal to each other. The outer side surfaces of the two first projections 32 located at opposite ends in the longitudinal direction of the first body 31 (in the present embodiment, the X-axis direction) are, for example, flush with the outer side surfaces of the first body 31.

The first recesses 33 are separated from each other by the first projections 32. Each first recess 33 is recessed from the central region of the semiconductor element 40 in plan view. The first recess 33 is recessed from distal ends of the first projections 32 toward the first body 31 in plan view. The first recess 33 corresponds to a space surrounded by the first body 31 and the two first projections 32 located next to each other in the X-axis direction. The first recess 33 has a shape such that the bottom end of the first recess 33 (i.e., end located close to the first body 31) is closed by the first body 31. As illustrated in FIG. 3, the first recess 33 extends through the connection pad 30 in the thickness-wise direction (in the present embodiment, the Z-axis direction).

### Structure of Connection Pad 35

As illustrated in FIG. 4, for example, the connection pads 35 are arranged in a peripheral region of the upper surface of the substrate body 21 in plan view. The connection pads 35 are arranged in or along the peripheral portion of the mount region in which the semiconductor element 40 is mounted. The connection pads 35 are arranged in the peripheral portion of the mount region to form a peripheral pattern in plan view. The connection pads 35 are separated from each other. The connection pads 35 are electrically insulated from each other. The connection pads 35 are separated from the connection pads 30. The connection pads 35 are electrically insulated from the connection pads 30.

The wiring layer 22 that forms the connection pads 35 extends, for example, from the peripheral portion of the mount region toward the outer edge of the substrate body 21. The wiring layer 22 that forms the connection pads 35 is partially covered by the solder resist layer 23.

### Structure of Semiconductor Element 40

As illustrated in FIG. 2, the semiconductor element 40 includes electrode pads 41 and 45 formed on a circuit formation surface (in the present embodiment, lower surface) of the semiconductor element 40. The semiconductor element 40 is flip-chip-mounted on the upper surface of the wiring substrate 20. The electrode pads 41 of the semiconductor element 40 are electrically connected to the connection pads 30 of the wiring substrate 20 by the bonding members 50. The electrode pads 45 of the semiconductor element 40 are electrically connected to the connection pads 35 of the wiring substrate 20 by the bonding members 55. Thus, the semiconductor element 40 is electrically connected to the wiring layer 22 of the wiring substrate 20 by the electrode pads 41 and 45 and the bonding members 50 and 55.

The semiconductor element 40 may be, for example, a logic chip such as a central processing unit (CPU) chip or a graphics processing unit (GPU) chip. Further, the semiconductor element 40 may be, for example, a memory chip such as a dynamic random-access memory (DRAM) chip, a static random-access memory (SRAM) chip, or a flash memory. Multiple semiconductor elements 40 including a combination of a logic chip and a memory chip may be mounted on the wiring substrate 20.

As illustrated in FIG. 1, the semiconductor element 40 is, for example, rectangular in plan view. However, the planar shape of the semiconductor element 40 is not limited to a rectangle and may be any shape. The planar size of the semiconductor element 40 may be, for example, approximately from 3 mm×3 mm to 12 mm×12 mm. The thickness of the semiconductor element 40 may be, for example, approximately 50 μm to 100 μm.

As illustrated in FIG. 2, the electrode pads 41 are each faced to the corresponding one of the connection pads 30. The electrode pads 45 are respectively faced to the connection pads 35. The electrode pads 41 and 45 each have the form of, for example, a post projecting downward from the circuit formation surface of the semiconductor element 40. In an example, the electrode pads 41 and 45 are each a metal post. In an example, the electrode pads 41 and 45 each have the form of a polygonal rod. The thickness of each of the electrode pads 41 and 45 may be, for example, approximately 2 μm to 50 μm. The material of the electrode pads 41 and 45 may be, for example, copper or a copper alloy.

The electrode pads 41 and 45 are each, for example, rectangular in plan view. However, the planar shape of the electrode pads 41 and 45 is not limited to a rectangle and may be any shape. As illustrated in FIG. 4, for example, each electrode pad 41 overlaps the entirety of the corresponding one of the connection pads 30 in plan view. In an example, the electrode pad 41 overlaps the first recesses 33 of the connection pad 30 in plan view.

### Structure of Bonding Member 50

As illustrated in FIG. 2, each bonding member 50 is arranged on the upper surface of the connection pad 30. The bonding member 50 is arranged between the upper surface of the connection pad 30 and the lower surface of the electrode pad 41. The bonding member 50 is bonded to the upper surface of the connection pad 30 and the lower surface of the electrode pad 41.

As illustrated in FIG. 1, the planar shape of the bonding members 50 is, for example, similar to the planar shape of the connection pads 30. Each bonding member 50 includes, for example, a second body 51 and multiple (in the present embodiment, five) second projections 52 projecting from the second body 51 in plan view. The bonding member 50 further includes one or more (in the present embodiment, four) second recesses 53 surrounded by the second body 51 and the (in the present embodiment, five) second projections 52 in plan view. In an example, the bonding member 50 is entirely comb-tooth-shaped in plan view.

The second body 51 is arranged on the upper surface of the first body 31. In an example, the second body 51 covers the entire upper surface of the first body 31. The second body 51 joins the second projections 52 to each other. The second body 51 is, for example, belt-shaped and extends in the X-axis direction. In other words, the second body 51 has a longitudinal direction that conforms to the X-axis direction. The second body 51 has, for example, a given width in the Y-axis direction. In other words, the second body 51 has a width-wise direction conforming to the Y-axis direction.

Each second projection 52 is arranged on the upper surface of the corresponding one of the first projections 32. In an example, the second projection 52 covers the entire upper surface of the first projection 32. Each second projection 52 projects from the second body 51 toward a central region of the semiconductor element 40 in plan view. The second projection 52 extends in a direction intersecting the longitudinal direction of the second body 51. In the present embodiment, the second projection 52 extends in the Y-axis direction, which is orthogonal to the X-axis direction, that is, the longitudinal direction of the second body 51. The second projection 52 is belt-shaped and extends in the Y-axis direction. The second projection 52 has a given width in the X-axis direction. The second projection 52 is formed continuously and integrally with the second body 51. The second projections 52 are arranged at intervals in the longitudinal direction (in the present embodiment, X-axis direction) of the second body 51. In an example, the second projections 52 project parallel to each other. In an example, the second projections 52 project from the second body 51 by the same length. In other words, the longitudinal dimension of the second projections 52 in the Y-axis direction are equal to each other.

The second recesses 53 are separated from each other by the second projections 52. Each second recess 53 is recessed from the central region toward the peripheral region of the semiconductor element 40 in plan view. The second recess 53 is recessed from distal ends of the second projections 52 toward the second body 51 in plan view. The second recess 53 corresponds to a space surrounded by the second body 51 and the two second projections 52 located next to each other in the X-axis direction. The second recess 53 overlaps the corresponding one of the first recesses 33 in plan view. The second recess 53 is in communication with the first recess 33. The second recess 53 has a shape such that the bottom end of the second recess 53 (i.e., end located close to the second body 51) is closed by the second body 51. As illustrated in FIG. 3, the second recess 53 extends through the bonding member 50 in the thickness-wise direction (in the present embodiment, the Z-axis direction).

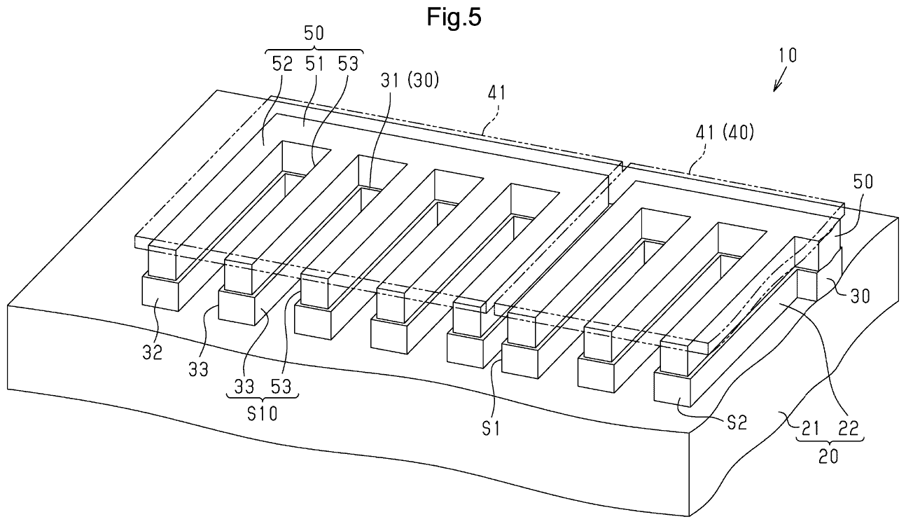

As illustrated in FIG. 5, the bonding member 50 fills a gap between the upper surface of the connection pad 30 and the lower surface of the electrode pad 41. The bonding member 50 is in contact with the upper surface of the connection pad 30 and the lower surface of the electrode pad 41 with no gap in between. In the bonding member 50, the second body 51 and the second projections 52 are continuously formed on the entire upper surface of the connection pad 30. In addition, the second body 51 and the second projections 52 close the bottom end of the second recess 53. Also, the first body 31 and the first projections 32 close the bottom end of the first recess 33. Thus, the upper surface of the substrate body 21, the wall surface of the first recess 33, the wall surface of the second recesses 53, and the lower surface of the electrode pad 41 define a first space S10 that is closed in the form of a dead end. That is, the first space S10 is open in a single direction. The first space S10 is in communication with the gap S2 through only the opening of the first recess 33 and the opening of the second recess 53. The first space S10 is separated from other spaces excluding the gap S2 by the connection pad 30 and the bonding member 50. The connection pads 30 and the bonding members 50 are used as partition walls that separate the first space S10 from the other spaces.

### Structure of Bonding Member 55

As illustrated in FIG. 2, each bonding member 55 is arranged on the upper surface of the corresponding one of the connection pads 35. The bonding member 55 is arranged between the upper surface of the connection pad 35 and the lower surface of the corresponding one of the electrode pads 45. The bonding member 55 is bonded to the upper surface of the connection pad 35 and the lower surface of the electrode pad 45.

As illustrated in FIG. 1, the planar shape of the bonding members 55 is, for example, similar to the planar shape of the connection pads 35. Each of the bonding members 50 is, for example, rectangular in plan view.

The bonding members 50 and 55 may be, for example, a tin (Sn) layer or a solder layer. The material of the solder layer may be, for example, lead-free solder having a Sn-silver (Ag) base, a Sn—Cu base, or a Sn—Ag—Cu base.

### Structure of Encapsulation Resin 60

As illustrated in FIG. 2, the encapsulation resin 60 is arranged between the upper surface of the substrate body 21 and the lower surface of the semiconductor element 40. The encapsulation resin 60 fills a gap between the upper surface of the substrate body 21 and the lower surface of the semiconductor element 40. The encapsulation resin 60 covers the entire upper surface of the substrate body 21 exposed from the solder resist layer 23, the entire surface of the connection pads 30 and 35, the entire surface of the bonding members 50 and 55, and the entire surface of the electrode pads 41 and 45. The encapsulation resin 60 fills the opening 23X in the solder resist layer 23. The encapsulation resin 60 covers the entire upper surface of the solder resist layer 23. The encapsulation resin 60 encapsulates the semiconductor element 40. The semiconductor element 40 is embedded in the encapsulation resin 60. At least the lower surface and side surface of the semiconductor element 40 are embedded in the encapsulation resin 60. In the example illustrated in FIG. 2, the encapsulation resin 60 covers the entire lower surface and the entire side surface of the semiconductor element 40. In an example, the encapsulation resin 60 exposes the entire upper surface of the semiconductor element 40.

As illustrated in FIG. 1, the encapsulation resin 60 fills the first recesses 33 and the second recesses 53. The encapsulation resin 60 fills the first space S10, which is surrounded by the upper surface of the substrate body 21, the inner surface of the first recess 33, the inner surface of the second recess 53, and the lower surface of the electrode pads 41. The encapsulation resin 60 fills the gaps S1, S2, S3.

The encapsulation resin 60 includes, for example, a void 61. In the example illustrated in FIG. 1, the encapsulation resin 60 includes four voids 61. The voids 61 are located in the first spaces S10. In other words, the voids 61 are located in the first recess 33 and the second recesses 53. In an example, the voids 61 are located at the bottom ends of the first spaces S10. The voids 61 may be located in all of the first spaces S10 or in only some of the first spaces S10. In the encapsulation resin 60 illustrated in FIG. 1, the voids 61 are located in some of the first spaces S10. The voids 61 are not located in spaces between two of the connection pads 30 located next to each other, that is, the gaps S1, S2, S3.

The material of the encapsulation resin 60 may be, for example, a non-photosensitive insulating resin containing a thermosetting resin as a main component. The material of the encapsulation resin 60 may be, for example, an insulating resin, such as epoxy resin or polyimide resin, or a resin material obtained by mixing the resin with a filler such as silica or alumina. The encapsulation resin 60 may be, for example, a mold resin.

As illustrated in FIGS. 2 and 3, the external connection terminals 70 are formed on the lower surface of the substrate body 21 of the wiring substrate 20. The external connection terminals 70 are, for example, connection terminals for electrical connection to pads arranged on a mount substrate such as a motherboard (not illustrated). The external connection terminals 70 may be, for example, solder balls or lead pins. In the present example, the external connection terminals 70 are solder balls.

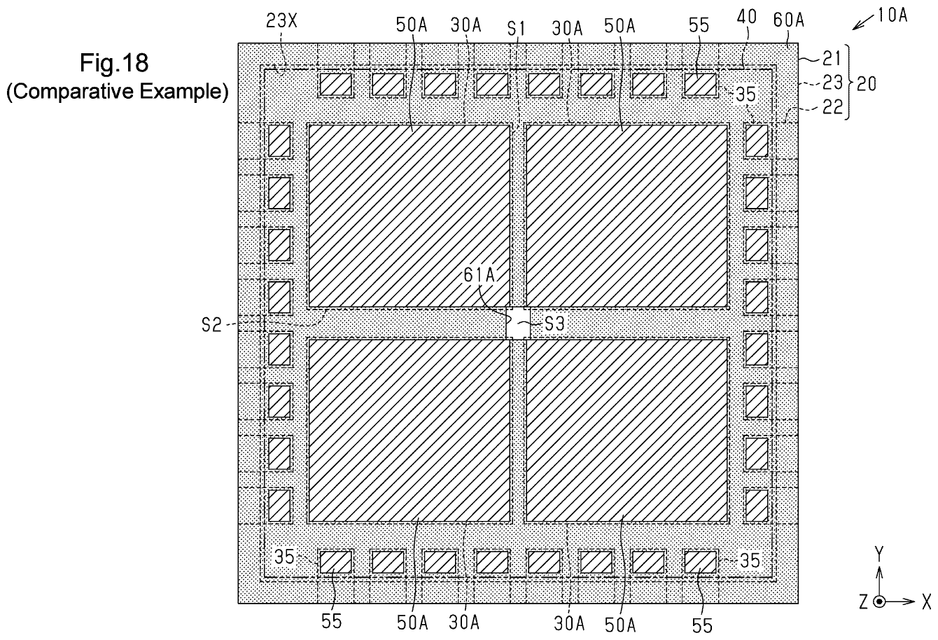

A comparative example of a semiconductor device 10A will now be described with reference to FIG. 18.

The semiconductor device 10A includes connection pads 30A and bonding members 50A arranged on the connection pads 30A. The planar shape of each connection pad 30A is a rectangle. The planar shape of each bonding member 50A is a rectangle. In the semiconductor device 10A, a void 61A may be formed in an encapsulation resin 60A. In the example illustrated in FIG. 18, the void 61A is formed in the gaps S2 and S3, each of which is a space between two of the connection pads 30A located next to each other. When the void 61A is formed in the gaps S2 and S3, each connection pad 30A is partially exposed in the void 61A. When the void 61A is formed as described above and, for example, heat is applied to connect the semiconductor device 10A to a mount substrate such as a motherboard, the bonding members 50A may melt and flow into the void 61A. The bonding members 50A flowing into the void 61A may form a short circuit between ones of the connection pads 30A located next to each other. As described above, when the void 61A is formed in a space between ones of the connection pads 30A located next to each other, a short defect may occur between the ones of the connection pads 30A.

By contrast, as illustrated in FIG. 5, in the semiconductor device 10 of the present embodiment, the connection pads 30 include the first recesses 33, and the bonding members 50 include the second recesses 53. The first space S10 is surrounded by the first recess 33, the second recess 53, the substrate body 21, and the electrode pad 41 and is closed in the form of a dead end. This shape facilitates formation of the void 61 (refer to FIG. 1) in the first space S10. With this structure, as illustrated in FIG. 1, the void 61 is intentionally formed in the first space S10, which is located in the connection pad 30. This limits formation of the void 61 in the space between ones of the connection pads 30 located next to each other, that is, the gaps S1, S2, and S3.

### Method for Manufacturing Semiconductor Device 10

A method for manufacturing the semiconductor device 10 will now be described. To facilitate understanding, portions that will become elements of the semiconductor device 10 are given the same reference characters as the final elements.

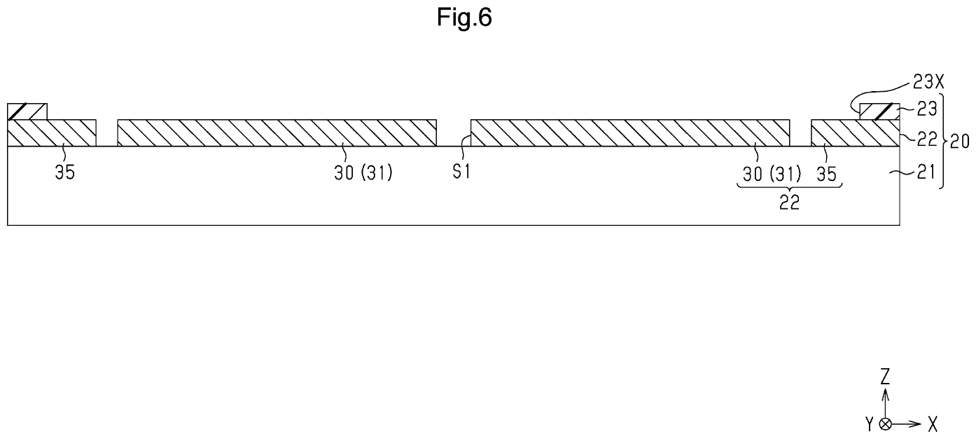

In the step illustrated in FIG. 6, a wiring substrate 20 is prepared. The wiring substrate 20 includes the substrate body 21, the wiring layer 22 including the connection pads 30 and 35, and the solder resist layer 23 having the opening 23X. The wiring substrate 20 may be manufactured through a known manufacturing process, which will not be described in detail.

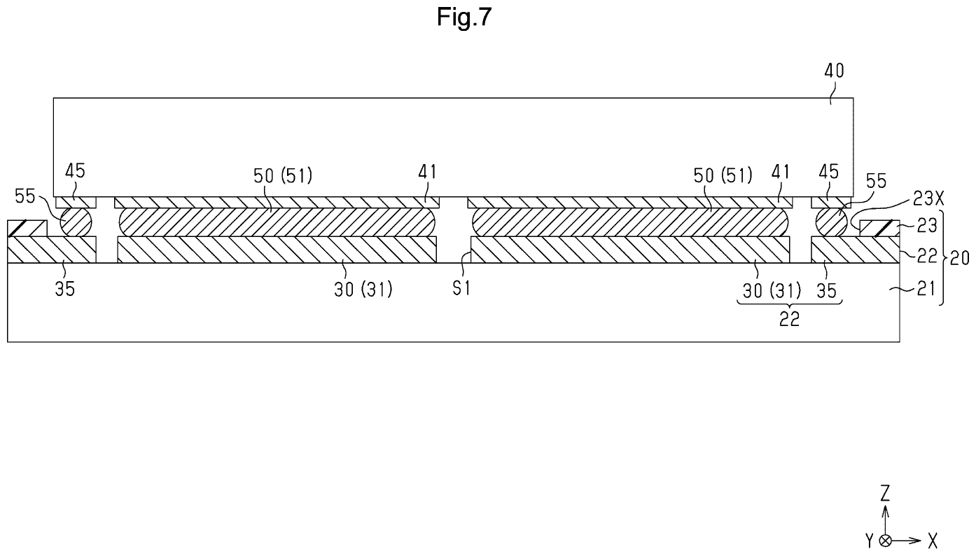

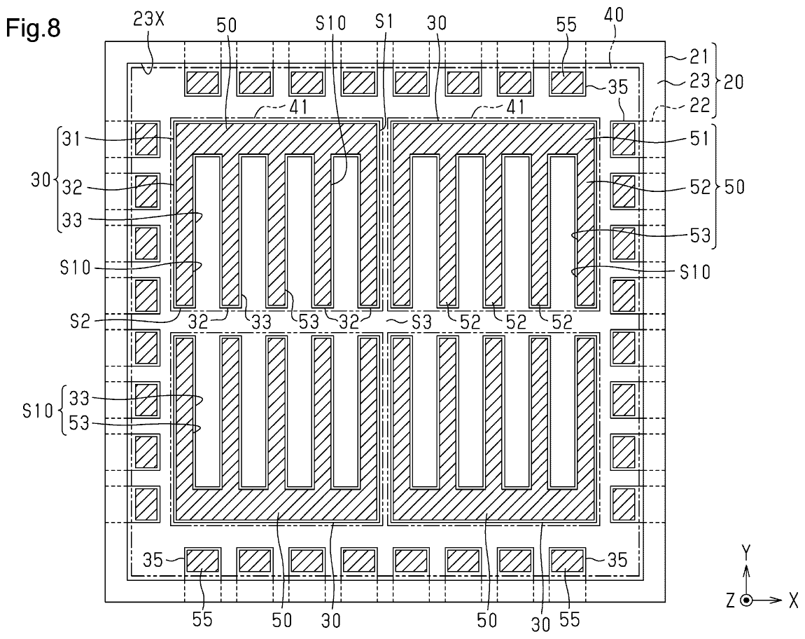

In the step illustrated in FIGS. 7 and 8, a semiconductor element 40 is prepared. As illustrated in FIG. 7, the semiconductor element 40 includes the electrode pads 41 and 45 formed on the circuit formation surface (in the present embodiment, lower surface). Subsequently, the semiconductor element 40 is mounted on the connection pads 30 and 35 of the wiring substrate 20. In an example, the electrode pads 41 and 45 of the semiconductor element 40 are bonded to the connection pads 30 and 35 of the wiring substrate 20 by the bonding members 50 and 55. When the bonding members 50 and 55 are formed of a solder layer, flux (not illustrated) is appropriately applied to the connection pads 30 and 35, and then the connection pads 30 and 35 and the electrode pads 41 and 45 are aligned with each other with the bonding members 50 and 55 located in between. Subsequently, a reflow process is performed at a temperature of approximately 230° C. to 260° C. This melts the bonding members 50 and 55, which are formed of a solder layer. the bonding members 50 and 55 electrically connect the connection pads 30 and 35 to the electrode pads 41 and 45. In this state, as illustrated in FIG. 8, the semiconductor element 40 is located overlapping the opening 23X in the solder resist layer 23 in plan view. The connection pads 30 and 35 and the bonding members 50 and 55 are exposed from the opening 23X of the solder resist layer 23.

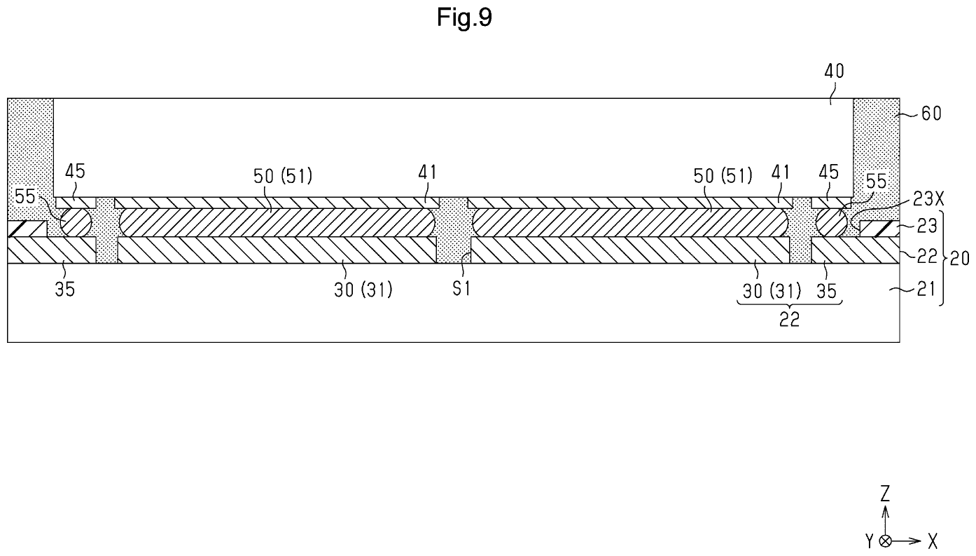

In the step illustrated in FIG. 9, the encapsulation resin 60 is formed between the wiring substrate 20 and the semiconductor element 40. The encapsulation resin 60 fills the gap between the upper surface of the substrate body 21 and the lower surface of the semiconductor element 40. At least the lower surface and side surface of the semiconductor element 40 are embedded in the encapsulation resin 60. The encapsulation resin 60 may be formed, for example, through a resin molding process. In an example, when a thermosetting molding resin is used as the material of the encapsulation resin 60, the structural body illustrated in FIGS. 7 and 8 is received in a mold (not illustrated). Pressure (e.g., 5 MPa to 10 MPa) is applied to the mold to transfer the liquidized molding resin into the mold. Then, the molding resin is heated and cured at a temperature of approximately 180° C. to form the encapsulation resin 60. When the encapsulation process is completed, the structural body including the encapsulation resin 60 is taken out from the mold. The process for filling the mold with the mold resin includes, for example, transfer molding, compression molding, and injection molding. When the encapsulation resin 60 covers the upper surface of the semiconductor element 40, for example, the semiconductor element 40 and the encapsulation resin 60 are thinned from the upper surface. In an example, the upper surface of the encapsulation resin 60 and the upper surface of the semiconductor element 40 are ground by backgrinding to thin the semiconductor element 40 and the encapsulation resin 60. As a result, the upper surface of the encapsulation resin 60 is flush with the upper surface of the semiconductor element 40.

Subsequently, the external connection terminals 70, which are illustrated in FIG. 2, are formed on the lower surface of the wiring substrate 20. The manufacturing steps described above manufacture the semiconductor device 10 of the present embodiment.

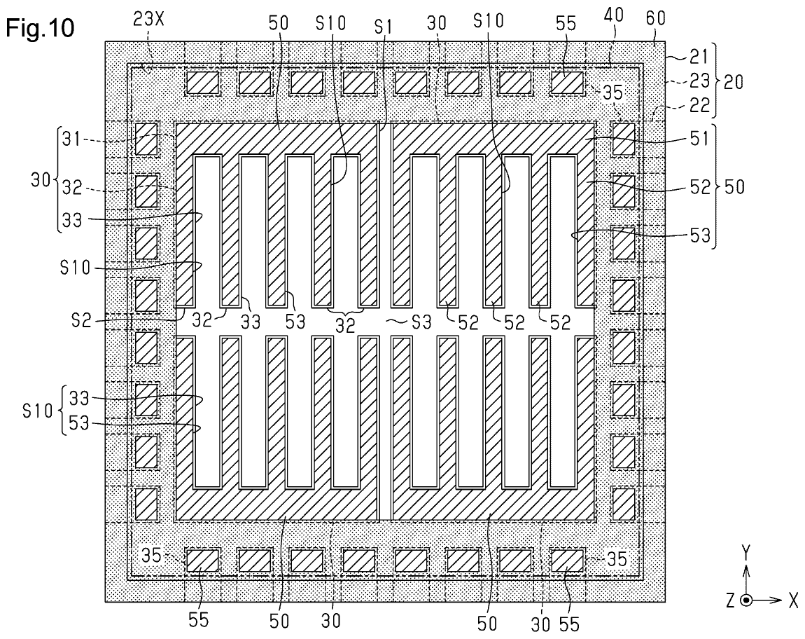

FIGS. 10 to 12 are each a schematic diagram illustrating an example of the encapsulation resin 60, which is liquidized in the step illustrated in FIG. 9, flowing on the wiring substrate 20. The flow of the liquid encapsulation resin 60 when supplied from the peripheral region of the wiring substrate 20 will now be described.

As illustrated in FIG. 10, when the liquidized encapsulation resin 60 is supplied to the peripheral region of the wiring substrate 20, the encapsulation resin 60 flows to cover the peripheral region of the wiring substrate 20 along the entire perimeter. The encapsulation resin 60 flows to cover the peripheral region of the wiring substrate 20 that is located outside the four bonding members 50 along the entire perimeter. In an example, the encapsulation resin 60 flows to cover the solder resist layer 23 and the connection pads 35. In an example, the encapsulation resin 60 flows to fill the gap between the connection pad 30 and the connection pad 35. In this state, the encapsulation resin 60 does not flow to the gaps S1, S2, and S3.

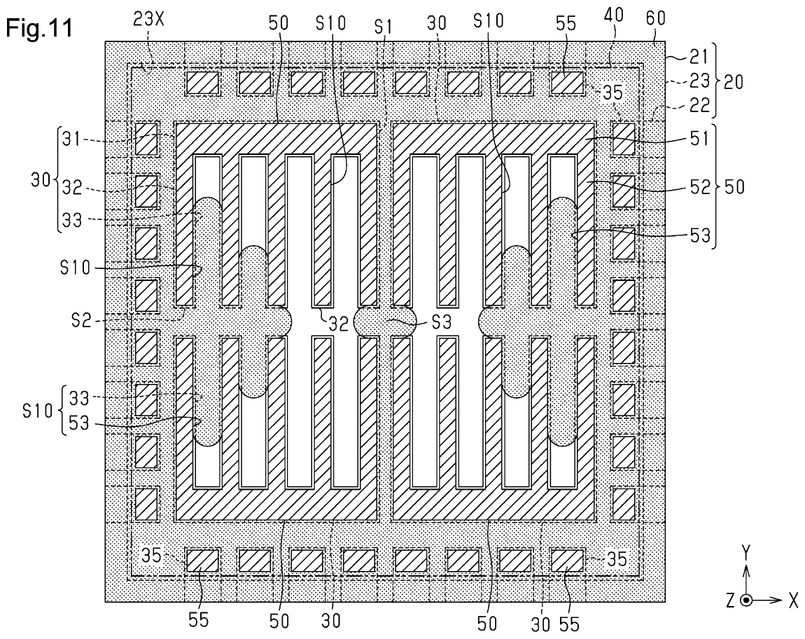

Subsequently, as illustrated in FIG. 11, the encapsulation resin 60 flows from the peripheral region of the wiring substrate 20 to inner parts of the gaps S1 and S2. The encapsulation resin 60, flowing in the inner part of the gap S1, spreads toward the gap S3 through the gap S1. In an example, as illustrated in FIG. 11, while the encapsulation resin 60 flows from the upper part of the peripheral region toward the gap S3, the encapsulation resin 60 flows from the lower part of the peripheral region toward the gap S3. In FIG. 11, the encapsulation resin 60 flowing from the upper side of the peripheral region toward the gap S3 and the encapsulation resin 60 flowing from the lower side of the peripheral region toward the gap S3 converge at the gap S3. As described above, after converging at the gap S3, the encapsulation resin 60 spreads from the gap S3 in the X-axis direction. In the present example, as illustrated in FIG. 11, the encapsulation resin 60 flows from the gap S3 leftward and rightward. In other words, after converging at the gap S3, the encapsulation resin 60 spreads from the gap S3 to the gap S2 in the X-axis direction. In this state, the gaps S1 and S3 are filled by the encapsulation resin 60.

Further, when spreading from the peripheral region of the wiring substrate 20 to the inner part of the gap S2, the encapsulation resin 60 flows to spread toward the gap S3 through the gap S2 and spread from the gap S2 to the inner part of the first spaces S10 located at the connection pads 30 and the bonding members 50. In an example, as illustrated in FIG. 11, while the encapsulation resin 60 flows from the left part of the peripheral region toward the gap S3, the encapsulation resin 60 flows from the right part of the peripheral region toward the gap S3. The encapsulation resin 60 flows to spread to the inner parts of the first spaces S10 in order of proximity to the peripheral region of the wiring substrate 20.

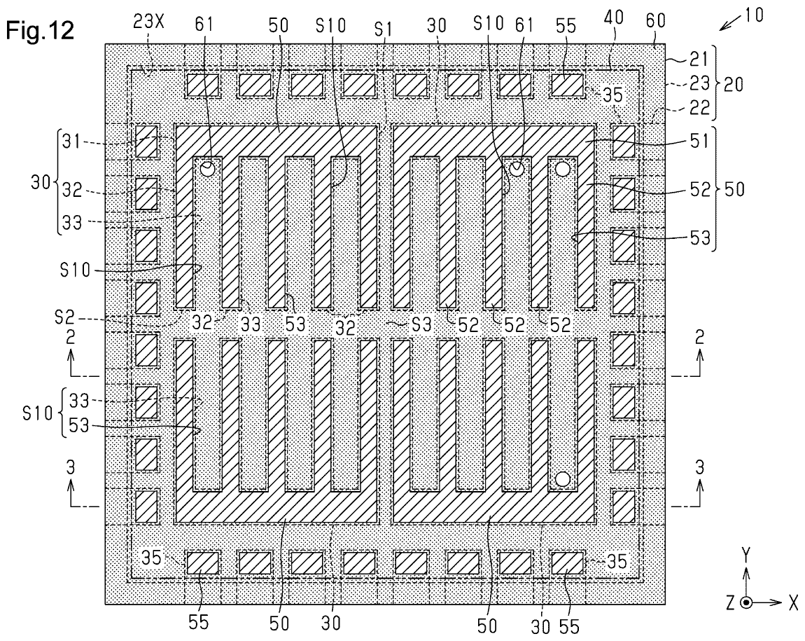

Subsequently, in the same manner, the encapsulation resin 60 flows to spread toward the gap S3 through the gap S2 and spread from the gap S2 to the inner parts of the first spaces S10. As a result, as illustrated in FIG. 12, the encapsulation resin 60 spreads on the entire upper surface of the wiring substrate 20. Thus, the encapsulation resin 60 fills the gaps S1, S2, and S3 and all of the first spaces S10.

Each first space S10 is closed in the form of a dead end. That is, the first space S10 is open in a single direction. In the example illustrated in FIG. 12, the first space S10 is in communication with the gap S2 through only the opening of the first recess 33 and the opening of the second recess 53. Thus, the encapsulation resin 60 flows into the first spaces S10 from only the opening of the first recess 33 and the opening of the second recesses 53. That is, the direction in which the encapsulation resin 60 flows into the first space S10 is restricted to one direction. The first space S10 having the structure described above facilitates formation of the void 61. As described above, the first space S10, in which the void 61 is likely to be formed, is formed. This facilitates formation of the void 61 in the first space S10. Since the void 61 is formed in the first space S10, the fluidity of the encapsulation resin 60 is improved in spaces other than the first space S10, namely, the gaps S1, S2, and S3. This limits formation of the void 61 in the gaps S1, S2, and S3, which are the spaces between connection pads 30 located next to each other.

The present embodiment has the advantages described below.

(1) The semiconductor device 10 includes the wiring substrate 20 including the connection pads 30, the semiconductor element 40 including the electrode pads 41, the bonding members 50 bonding the connection pads 30 to the electrode pads 41, and the encapsulation resin 60 arranged between the wiring substrate 20 and the semiconductor element 40. Each connection pad 30 includes the first body 31, the first projections 32 projecting from the first body 31 toward the central region of the semiconductor element 40 in plan view, and the first recess 33 surrounded by the first body 31 and the first projections 32 in plan view. Each bonding member 50 includes the second body 51 formed on the first body 31 and the second projections 52 formed on the first projections 32 and projecting from the second body 51 toward the central region of the semiconductor element 40 in plan view. The bonding member 50 further includes the second recesses 53 surrounded by the second body 51 and the second projections 52 in plan view.

In this structure, the connection pad 30 includes the first recess 33 surrounded by the first body 31 and the first projections 32. The bonding member 50 includes the second recess 53 surrounded by the second body 51 and the second projections 52. The first recess 33 and the second recess 53 each have a shape such that the bottom end is closed by the first body 31 and the second body 51. The first space S10 surrounded by the first recess 33 and the second recess 53 is closed in the form of a dead end. The first space S10 is shaped to facilitate formation of the void 61 when the encapsulation resin 60 is formed. As described above, the first space S10, in which the void 61 is likely to be formed, is formed. This facilitates formation of the void 61 in the first space S10. Since the void 61 is formed in the first space S10, the fluidity of the encapsulation resin 60 is improved in spaces other than the first space S10, namely, the gaps S1, S2, and S3. This limits formation of the void 61 in the gaps S1, S2, and S3, which are the spaces between connection pads 30 located next to each other. Consequently, occurrence of a short defect between two connection pads 30 due to formation of the void 61 is limited in a preferred manner. As a result, the reliability of electrical connection between the wiring substrate 20 and the semiconductor element 40 is improved.

(2) The first space S10 surrounded by the upper surface of the substrate body 21, the wall surface of the first recess 33, the wall surface of the second recesses 53, and the lower surface of the electrode pad 41 is open in a single direction. The direction in which the resin flows into the first space S10 is restricted in one direction. This facilitates formation of the void 61 in the inner part of the first space S10. Thus, formation of the void 61 in the gaps S1, S2, and S3 is limited in a preferred manner.

(3) The first space S10 allows a difference in speed between the encapsulation resin 60 flowing in the gap S1 and the encapsulation resin 60 flowing in the gap S2, which is in communication with the first space S10. The encapsulation resin 60 flowing through the gap S1 first fills the gap S3, which is most likely to form a short circuit. When the encapsulation resin 60 having filled the gap S3 and the encapsulation resin 60 flowing through the gap S2 converge, a void may be formed. Such a void is forced toward the first space S10. Consequently, the void does not remain in the gaps S1, S2, S3, which have the possibility of having a short defect.

(4) The encapsulation resin 60 includes the void 61 located in the first space S10. In other words, the void 61 is formed in the first space S10 located between the two first projections 32 on the single connection pad 30. With this structure, when the bonding member 50 flows into the void 61, the bonding member 50 electrically connects two of the first projections 32 arranged in the same connection pad 30. That is, even when the bonding member 50 flows into the void 61, the bonding member 50 electrically connects two of the first projections 32 that have the same potential. Thus, even when the bonding member 50 flows into the void 61, a short defect does not occur.

(5) As described above, the first space S10 located between two of the first projections 32 in the single connection pad 30 is formed to have a structure that facilitates formation of the void 61. This allows the void 61 to be formed in the first space S10, in which a short defect does not occur. The void 61 is formed in the first space S10. This limits formation of the void 61 in the gaps S1, S2, and S3, which have the possibility of having a short defect. As described above, the position where the void 61 is formed is moved to a position where the quality of the product is not affected, that is, a position where there is no possibility of having a short defect. In other words, the position where the void 61 is likely to be formed is controlled.

(6) The connection pad 30 includes three or more (in the present embodiment, five) first projections 32 and multiple (in the present embodiment, four) first recesses 33. The bonding member 50 includes three or more (in the present embodiment, five) second projections 52 and multiple (in the present embodiment, four) second recesses 53. The first recesses 33 are separated from each other by the first projections 32. The second recesses 53 are separated from each other by the second projections 52.

In this structure, each connection pad 30 includes multiple (in the present embodiment, four) first spaces S10. When each connection pad 30 includes a large number of the first spaces S10, in which the void 61 is likely to be formed, formation of the voids 61 in spaces (in the present embodiment, the gap S1, S2, and S3) other than the first space S10 is limited in a further preferred manner.

### Modified Examples

The above embodiment may be modified as follows. The embodiment and the following modified examples may be combined as long as the combined modified examples remain technically consistent with each other.

The structure of the connection pads 30 in the embodiment may be changed. Also, the structure of the bonding member 50 may be changed.

The number of the first projections 32 of the connection pad 30 is not particularly limited. Also, the number of the second projections 52 of the bonding member 50 is not particularly limited.

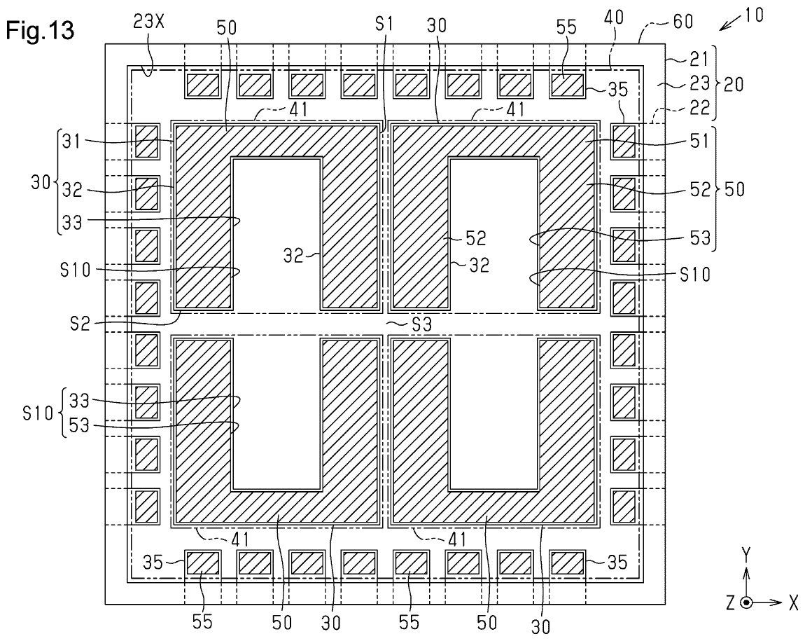

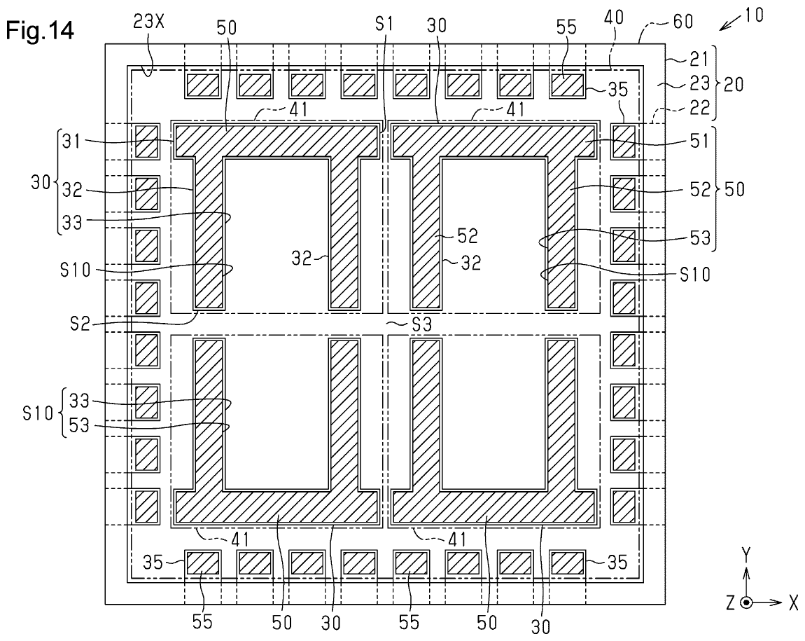

In an example, as illustrated in FIG. 13, the planar shape of the connection pad 30 may be changed. In this example, the connection pad 30 includes the first body 31, two first projections 32, and one first recess 33. In this case, the planar shape of the bonding member 50 may be changed. In this example, the bonding member 50 includes the second body 51, two second projections 52, and one second recess 53. FIG. 13 does not illustrate the voids 61 (refer to FIG. 1) that may be formed in the first spaces S10. Also, FIGS. 14 to 17, which will be described later, do not illustrate the voids 61 that may be formed in the first spaces S10.

In an example, as illustrated in FIG. 14, the first body 31 may project outward from the outer side surfaces of the first projections 32. In this case, the second body 51 may project outward from the outer side surfaces of the second projections 52.

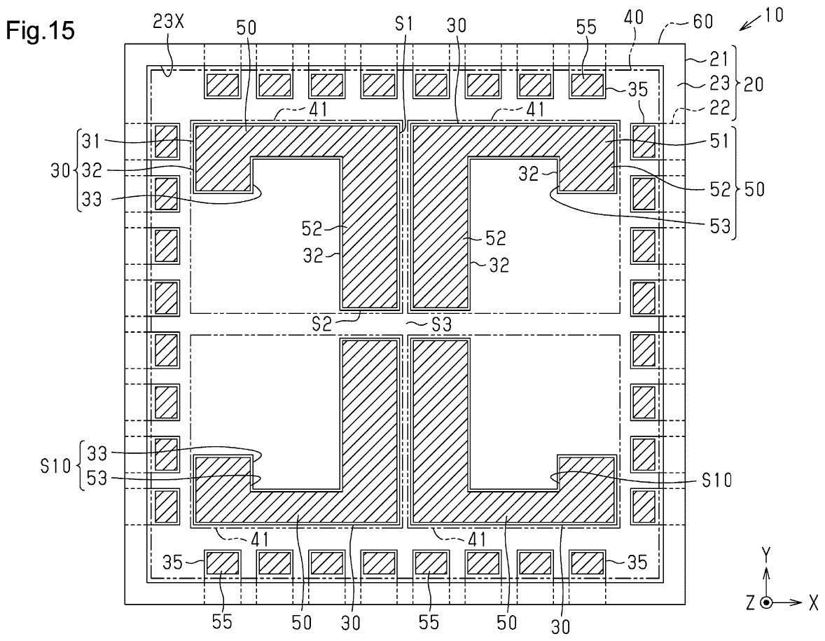

In an example, as illustrated in FIG. 15, the length of projection from the first body 31 may differ between the first projections 32. In this modified example, one of the two first projections 32 located closer to the peripheral region of the wiring substrate 20 projects from the first body 31 less than the other of the two first projections 32. In this case, the length of projection from the second body 51 may differ between the second projections 52. In this modified example, one of the two second projections 52 located closer to the peripheral region of the wiring substrate 20 projects from the second body 51 less than the other of the two second projections 52.

In the present embodiment, the number of connection pads 30 is not particularly limited. Also, the number of bonding members 50 is not particularly limited.

In the present embodiment, the layout of the connection pads 30 is not particularly limited. Also, the layout of the bonding members 50 is not particularly limited. The layout of the connection pads 30 and the bonding members 50 may be changed to a layout other than the matrix pattern.

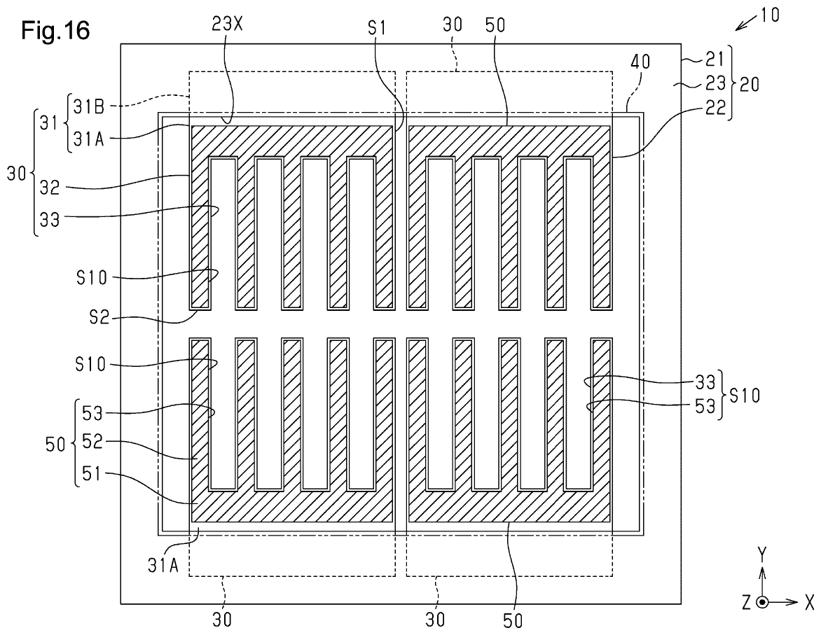

In an example, as illustrated in FIG. 16, the connection pads 35 may be omitted.

In the embodiment, the opening 23X of the solder resist layer 23 exposes the entirety of the connection pads 30. Alternatively, the structure may be changed as follows.

In an example, as illustrated in FIG. 16, the opening 23X of the solder resist layer 23 exposes a portion of the connection pads 30. The opening 23X exposes the first projections 32, the first recess 33, and a first part 31A of the first body 31 that is connected to the first projections 32. In this case, the first body 31 includes the first part 31A exposed from the opening 23X and a second part 31B covered by the solder resist layer 23. In the present modified example, the first projections 32 project from the first part 31A of the first body 31 toward the central region of the semiconductor element 40 in plan view. In the present modified example, the second body 51 of the bonding member 50 is arranged on the upper surface of the first part 31A of the first body 31.

In an example, as illustrated in FIG. 16, the semiconductor element 40 may overlap the solder resist layer 23 in plan view. For example, the semiconductor element 40 may be greater in planar size than the opening 23X of the solder resist layer 23.

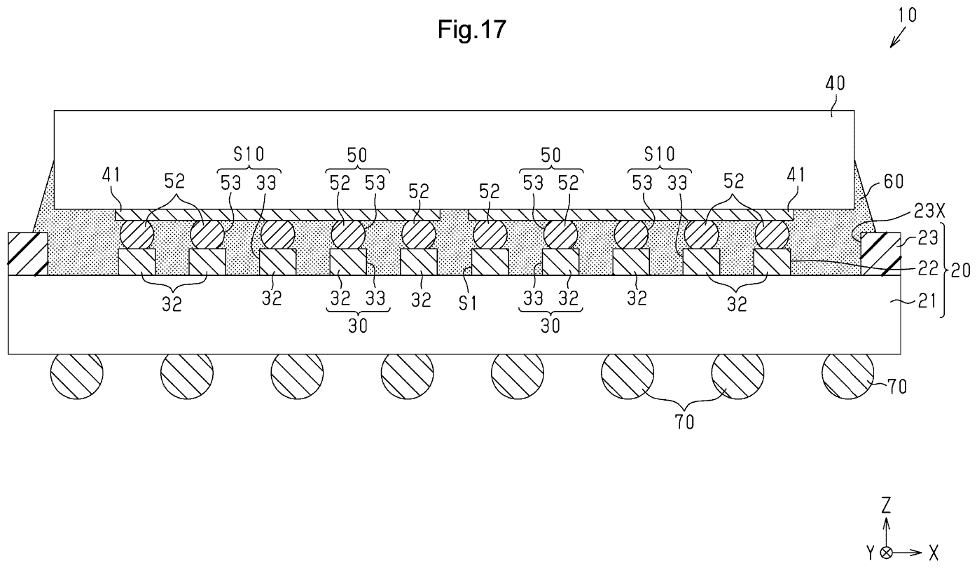

In an example, as illustrated in FIG. 17, the encapsulation resin 60 may be embodied by an underfill resin filling the gap between the wiring substrate 20 and the semiconductor element 40.

In the embodiment, the structure of the wiring substrate 20 may be changed. In an example, the solder resist layer 23 may be omitted.

In the embodiment, the structure of the electrode pads 41 may be changed. For example, the planar shape of the electrode pads 41 may be changed in the same manner as the planar shape of the connection pads 30.

In the embodiment, the number of semiconductor elements 40 mounted on the wiring substrate 20 is not particularly limited. For example, multiple semiconductor elements 40 may be mounted on the wiring substrate 20.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a wiring substrate including a substrate body and connection pads formed on an upper surface of the substrate body;
a semiconductor element mounted on the wiring substrate and including electrode pads;
a bonding member bonding the connection pads to the electrode pads; and
an encapsulation resin arranged between the wiring substrate and the semiconductor element, wherein
the connection pads each include a first body, first projections projecting from the first body toward a central region of the semiconductor element in plan view, and a first recess surrounded by the first body and the first projections in plan view,
the bonding member includes a second body formed on the first body, second projections formed on the first projections and projecting from the second body toward the central region of the semiconductor element in plan view, and a second recess surrounded by the second body and the second projections in plan view, and
a first space surrounded by the upper surface of the substrate body, a wall surface of the first recess, a wall surface of the second recess, and a lower surface of each of the electrode pads is open in a single direction.

2. The semiconductor device according to claim 1, wherein the encapsulation resin includes a void in the first space.

3. The semiconductor device according to claim 1, wherein
the wiring substrate includes a solder resist layer formed on the upper surface of the substrate body,
the solder resist layer includes an opening extending through the solder resist layer in a thickness-wise direction of the solder resist layer, and
the opening exposes the first projections, the first recess, and at least a part of the first body, the part of the first body being connected to the first projections.

4. The semiconductor device according to claim 3, wherein the opening entirely exposes the connection pads.

5. The semiconductor device according to claim 3, wherein
the first body includes a first part exposed from the opening and a second part covered by the solder resist layer,
the first projections project from the first part toward the central region of the semiconductor element in plan view, and
the second body is arranged on the first part.

6. The semiconductor device according to claim 1, wherein
the first projections include three or more first projections,
the first recess is one of first recesses included in each of the connection pads,
the first recesses are separated from each other by the three or more first projections,
the second projections include three or more second projections,
the second recess is one of second recesses included in the bonding member, and
the second recesses are separated from each other by the three or more second projections.

7. The semiconductor device according to claim 1, wherein the first projections differ from each other in length of projection from the first body.

8. The semiconductor device according to claim 1, wherein
the encapsulation resin entirely covers a side surface of the semiconductor element, and
the encapsulation resin entirely exposes an upper surface of the semiconductor element.

9. The semiconductor device according to claim 1, wherein
the connection pads are arranged in a matrix pattern in plan view, and
two of the connection pads that are next to each other are arranged in proximity to each other.
